(19) United States
(12) Patent Application Publication
(10) Pub. No.: US 2004/0266030 A1
(43) Pub. Date: Dec. 30, 2004

(54) Method for fabricating ferroelectric random access memory device having capacitor with merged top-electrode and plate-line structure

(76) Inventor: Soon-Yong Kweon, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/734,865

(22) Filed: Dec. 12, 2003

(30) Foreign Application Priority Data
Jun. 30, 2003 (KR) 2003-43078

(51) Int. Cl. H01L 21/00; H01L 21/8242

(52) U.S. Cl. 438/3; 438/240

(57) ABSTRACT

The present invention relates to a method for fabricating a ferroelectric memory device. The method includes the steps of: forming a first insulation layer on a substrate; forming a storage node contact contacting to a partial portion of the substrate by passing through the first insulation layer; forming a stack pattern of a lower electrode contacting to the storage node contact and a hard mask on the first insulation layer; forming a second insulation layer on an entire surface of the resulting structure including the stack pattern; planarizing the second insulation layer until a surface of the hard mask is exposed; removing selectively the exposed hard mask to make a surface level of the lower electrode lower than that of the second insulation layer; and forming sequentially a ferroelectric layer and an upper electrode on the second insulation layer and the lower electrode.

### FIELD OF THE INVENTION

The present invention relates to a method for fabricating a semiconductor memory device; and, more particularly, to a method for fabricating a ferroelectric random access memory device.

### DESCRIPTION OF RELATED ARTS

It has been continuously attempted to develop a semiconductor memory device capable of operating a large scale of memory size and overcoming a limitation in refresh required by a dynamic random access memory (DRAM) device by employing a ferroelectric thin layer for a ferroelectric capacitor. Such ferroelectric random access memory (FeRAM) device using the ferroelectric thin layer is a nonvolatile memory device. That is, the FeRAM device has an advantage of retrieving stored information even if the power is turned off. Also, the FeRAM device has been recently highlighted as one of the next generation memory devices by having a compatible operation speed to a DRAM device. Especially, a merged top-electrode and plate-line (MTP) structure is recently adopted for a high density FeRAM device.

FIG. 1 is a cross-sectional view of a conventional FeRAM device with a MTP structure.

As shown, a device isolation layer 12 defining active regions is formed on a substrate 11, and a junction region such as a source/drain region is formed in the substrate 11. Also, a first insulation layer 14 is formed on an entire surface of the above resulting substrate structure.

Then, a storage node contact 15 contacted to the junction region 13 is formed by passing through the first insulation layer 14. Afterwards, a lower electrode 16 connected to the storage node contact 15 is formed on top of the first insulation layer 14.

A second insulation layer 17 encompasses the lower electrode 16 to isolate each neighboring electrode 16. Herein, the second insulation layer 17 and the lower electrode 16 are planarized at the same plane level.

Next, a ferroelectric layer 18 is formed on the second insulation layer 17 and the lower electrode 16, and an upper electrode 19 is then formed on the ferroelectric layer 18. Herein, the upper electrode 19 functions as a plateline as well.

To form the second insulation layer 17 in a manner to encompass the lower electrode 16, the lower electrode 16 is etched after being separated into one bit by one bit through a patterning process. After the etching of the lower electrode 16, the second insulation layer 17 is deposited thereon. Then, a chemical mechanical polishing (CMP) process is performed until a surface of the lower electrode 16 is exposed so that the second insulation layer 17 is planarized. However, it is necessary to perform the CMP process overly to make the surface of the lower electrode 16 exposed. Thus, there occurs a height difference X between the surface of the lower electrode 16 and the surface of the second insulation layer 17. Also, during the CMP process, such defect like a scratch caused by slurry occurs on the surface of the lower electrode 16, which is generally a metal layer. Particularly, if the height difference between the lower electrode 16 and the second insulation layer 17 is large, a crack may be induced when the ferroelectric layer 18 is deposited by a spin-on method. The crack degrades properties of an interface between the ferroelectric layer 18 and the lower electrode 16. Also, the crack causes a short circuit between the lower electrodes 16 and makes it difficult to obtain uniformity of a cell area.

### SUMMARY OF THE INVENTION

It is, therefore, an object of the present invention to provide a method for fabricating a ferroelectric random access memory device capable of minimizing a height difference between a lower electrode and an insulation layer during formation of a merged top-electrode and plate-line (MTP) structure wherein the lower electrode is encompassed by the insulation layer.

In accordance with an aspect of the present invention, there is provided a method for fabricating a ferroelectric memory device, including the steps of: forming a first insulation layer on a substrate; forming a storage node contact contacting to a partial portion of the substrate by passing through the first insulation layer; forming a stack pattern of a lower electrode contacting to the storage node contact and a hard mask on the first insulation layer; forming a second insulation layer on an entire surface of the resulting structure including the stack pattern; planarizing the second insulation layer until a surface of the hard mask is exposed; removing selectively the exposed hard mask to make a surface level of the lower electrode lower than that of the second insulation layer; and forming sequentially a ferroelectric layer and an upper electrode on the second insulation layer and the lower electrode.

### BRIEF DESCRIPTION OF THE DRAWING(S)

The above and other objects and features of the present invention will become apparent from the following description of the preferred embodiments given in conjunction with the accompanying drawings, in which:

FIG. 1 is a cross-sectional view of a conventional ferroelectric random access memory (FeRAM) device with a merged top-electrode and plate-line (MTP) structure; and

FIGS. 2A to 2F are cross-sectional views showing fabrication steps of a FeRAM device in accordance with a preferred embodiment of the present invention.

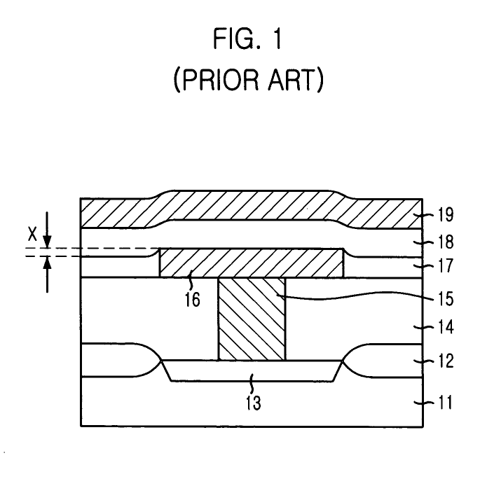

### DETAILED DESCRIPTION OF THE INVENTION

Hereinafter, detailed descriptions on a method for fabricating a ferroelectric random access memory (FeRAM) device with a merged top-electrode and plate-line (MTP) structure will be described with referenced to the accompanying drawings.

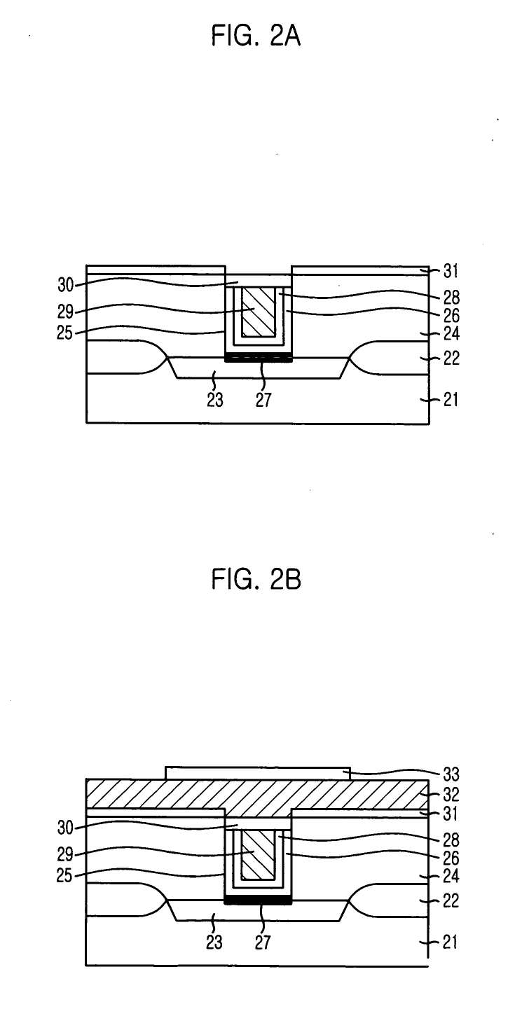

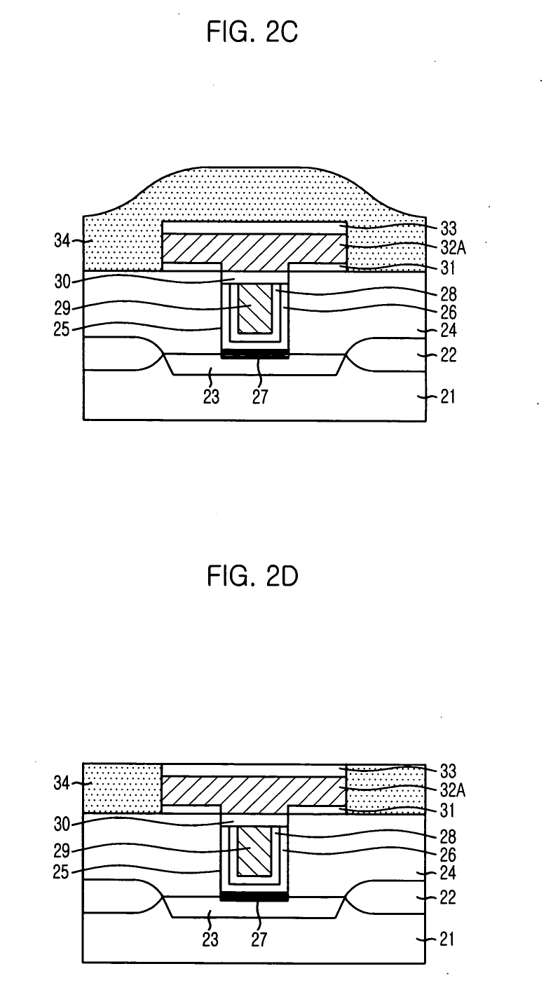

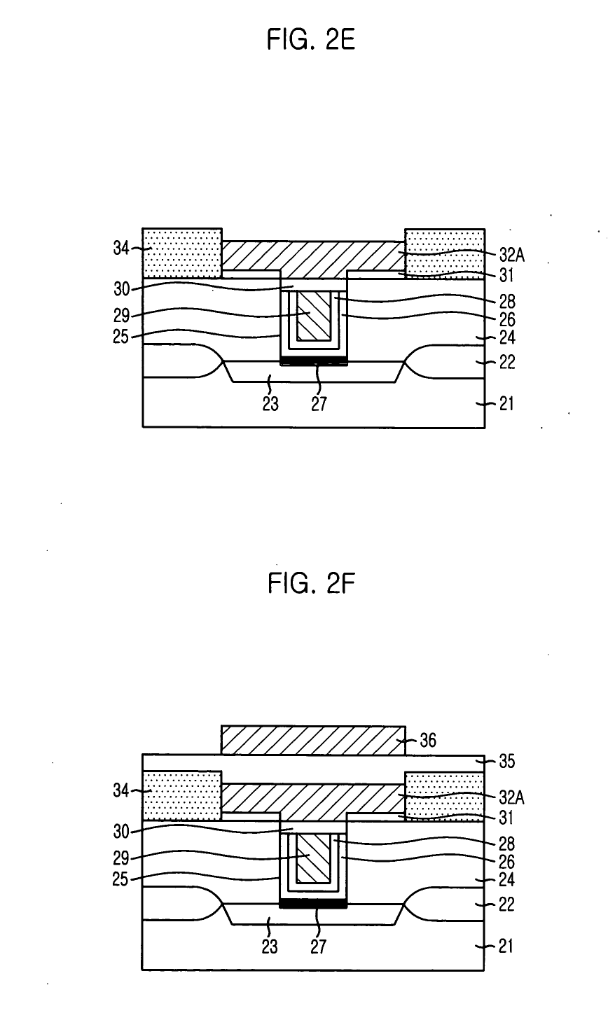

FIGS. 2A to 2F are cross-sectional views showing fabrication steps of a FeRAM device with a MTP structure fabricated in accordance with a preferred embodiment of the present invention.

Referring to FIG. 2A, a device isolation layer 22 defining an active region is formed on a substrate 21, and a junction region 23 such as a source/drain region is formed in the substrate 21. At this time, the junction region 23 is formed by ion implanting an n-type impurity.

Next, a first insulation layer 24 is deposited on the above resulting substrate structure and is planarized thereafter. Herein, the first insulation layer 24 is an oxide layer formed through a high density plasma (HDP) technique. After the planarization of the first insulation layer 24, the first insulation layer 24 is then etched by using a contact mask (not shown) to form a storage node contact hole 25 exposing the junction region 23.

Afterwards, a storage node contact buried into the storage node contact hole 25 is formed. For instance, titanium (Ti) and titanium nitride (TiN) are sequentially deposited on a structure including the first insulation layer 24 and the storage node contact hole 25 to form a TiN/Ti barrier layer 26. Then, a titanium silicide (TiSi₂) layer 27 is formed on an interface between the junction region 23 and the TiN/Ti barrier layer 26 through the use of a rapid thermal process (RTP) so to form an ohmic contact.

At this time, the RTP is carried out at a temperature of about 830° C. in an atmosphere of nitrogen (N₂) for about 20 seconds. Another technique can be also employed to form the TiSi₂ layer 27. For instance, a chemical vapor deposition (CVD) technique is used to form the TiSi₂ layer 27 simultaneous to the deposition of the TiN/Ti barrier layer 26. At this time, the RTP can be omitted.

Next, a first TiN layer 28 is deposited on the TiN/Ti barrier layer 26, and a tungsten (W) layer 29 is deposited thereon with a thick thickness. Thereafter, an etch-back process is applied to the above resulting deposition structure so to form a tungsten plug structure partially filled into the storage node contact hole 25. At this time, the first TiN layer 28 is for preventing reciprocal diffusions between the W layer 29 and the junction region 23. It is preferable for the first TiN layer 28 to have a thickness of about 200 Å. Also, a thickness of the W layer 29 is determined by the size of the tungsten plug. In case of about 0.30 μm diameter, the W layer 29 preferably has the thickness of about 3000 Å. For the formation of the tungsten plug structure, it is possible to omit the deposition of the first TiN layer 28 in case of using the CVD technique. It is also possible to completely fill the storage node contact hole 25 by depositing thickly the first TiN layer 28. In this case, it is not necessary to deposit the W layer 29.

Meanwhile, a depth of the etching for forming the tungsten plug structure depends on subsequent processes. Preferably, the etching process continues until reaching the depth ranging from about 500 Å to about 1500 Å.

Subsequent to the formation of the tungsten plug structure, the storage node contact hole 25 is completely filled by depositing a second TiN layer 30 on the above tungsten plug structure. At this time, the thickness of the second TiN layer 30 is determined by the depth of the above etching. For instance, if the etching proceeds to the depth of about 1000 Å, the thickness of the second TiN layer 30 is preferably about 1500 Å.

Next, the second TiN layer 30 is subjected to a CMP process so to be buried into the storage node contact hole 25. That is, a buried type TiN plug structure is formed.

An adhesion layer 31 is formed on top of the buried TiN plug structure. Then, the adhesion layer 31 is partially etched by performing an etching process with use of a mask so to open an upper part of the buried TiN plug structure. At this time, the adhesion layer 31 is made of alumina (Al₂O₃) or titanium oxide (TiO₂).

In case of forming the adhesion layer 31 with alumina, the deposition thickness of the alumina is thin enough to make the alumina be easily broken by a subsequent thermal process even without performing an etching process with use of a mask for opening the adhesion layer 31, so that the upper part of the buried TiN plug structure is opened. Therefore, the thickness of the alumina ranges from about 5 Å to about 100 Å. Herein, a rapid thermal process (RTP) is performed as the subsequent thermal process, and this RTP induces the alumina deposited on the upper part of the second TiN layer 30 to be cracked. At this time, thermal expansion coefficients of the tungsten layer 29 and the second TiN layer 30 are tenfold larger than silicon oxide used for the first insulation layer 24, and thus, the crack is induced only at the upper part of the second TiN layer 30 and the W layer 29. Herein, a temperature for the RTP ranges from about 400° C. to about 1000° C. Also, the RTP is carried out in an atmosphere of N₂ or Ar to prevent the second TiN layer 30 and the W layer 29 from being oxidated during the RTP. After the RTP, partially cracked portions of the alumina is cleaned with a cleaning agent of SC-1 formed by mixing ammonium hydroxide (NH₄OH), hydrogen peroxide (H₂O₂) and water (H₂O) in a ratio of about 1 to about 4 to about 20 so as to open the upper part of the second TiN layer 30.

Referring to FIG. 2B, a first conductive layer 32 and a hard mask 33 are sequentially deposited on the adhesion layer 31 and the opened upper part of the buried TiN structure. At this time, the first conductive layer 32 is deposited by using one of a CVD technique, a physical vapor deposition (PVD) technique, an atomic layer deposition (ALD) technique and plasma enhanced atomic layer deposition (PEALD) technique. Also, the first conductive layer 32 is made of a material selected from a group consisting of Pt, Ir, Ru, Re and Rh or a combination of the above materials. For instance, the first conductive layer 32 is formed by stacking Ir, IrO₂ and Pt. At this time, Ir, IrO₂ and Pt are deposited to a thickness ranging from about 100 Å to about 3000 Å, from about 10 Å to about 500 Å and from about 100 Å to about 5000 Å, respectively.

The hard mask 33 is made of TiN, tantalum nitride (TaN) or silicon oxide (SiOₓ) by using a CVD technique, a PVD technique or an ALD technique. Herein, the hard mask 33 is deposited to a thickness ranging from about 100 Å to about 2000 Å.

Next, a photosensitive layer is coated on the hard mask 33 and is then patterned through a photo-exposure and developing process to form a photosensitive pattern (not shown) defining a lower electrode. Thereafter, the hard mask 33 is patterned by using the photosensitive pattern as an etch mask. The photosensitive pattern is removed.

Referring to FIG. 2C, the first conductive layer 32 is etched one bit by one bit with use of the patterned hard mask 33 as an etch mask so as to form a lower electrode 32A. For the formation of the lower electrode 32A, the hard mask 33 is set to remain in a thickness ranging from about 100 Å to about 1000 Å. Also, the adhesion layer 31 beneath the first conductive layer 32 is also etched simultaneously.

Next, on an entire surface of the above resulting structure, a second insulation layer 34 is deposited to a thickness ranging from about 3000 Å to about 10000 Å. At this time, the second insulation layer 34 is made of a material selected from high density plasma (HDP) oxide, borophosphosilicate glass (BPSG), phosphosilicate glass (PSG), middle temperature oxide (MTO), high temperature oxide (HTP) and tetraethylorthosilicate (TEOS). Meanwhile, prior to forming the second insulation layer 34, it is possible to form another insulation layer for preventing diffusions of oxygen into the lower electrode 32A during the deposition of the second insulation layer 34. Such insulation layer for preventing the oxygen diffusion is formed with a material selected from a group consisting of Al₂O₃, silicon nitride (Si₃N₄) or silicon oxynitride (SiON).

Referring to FIG. 2D, the second insulation layer 34 is subjected to a CMP process performed before a surface of the hard mask 33 is exposed so to make a partial portion of the second insulation layer 34 planarized. Thereafter, a CMP process and an etch-back process are performed again to make the surface of the hard mask 33 exposed. Alternatively, the CMP process or the etch-back process can be performed at once to the second insulation layer 34 until the surface of the hard mask 33 is exposed.

By the above described series of processes, the hard mask 33 is exposed, and thus, the lower electrode 32A beneath the exposed hard mask 33 is also exposed, thereby being encompassed by the second insulation layer 34.

Referring to FIG. 2E, the hard mask 33 remained after patterning the lower electrode 32A is removed by using a wet etching or a dry etching process. For instance, for the wet etching process, such cleaning chemical as SC-1 or SPM formed by mixing sulfuric acid (H₂SO₄) and hydrogen peroxide (H₂O₂) in a ratio of about 4 to about 1 is used. At this time, the second insulation layer 34 can be partially damaged when the hard mask 33 is subjected to the wet etching process. However, the SC-1 cleaning chemical does not nearly etch the silicon oxide layer. The thickness of the remaining hard mask 33 determines a duration time of the wet etching process. Preferably, the wet etching process proceeds for about 10 seconds to about 1 hour. In addition to the use of the wet chemical, it is possible to use a mixed gas of Ar and Cl to remove the hard mask 33.

The above mentioned wet etching or dry etching process makes a surface of the lower electrode 32A exposed, and thus, the surface of the lower electrode 32A becomes lower than that of the second insulation layer 34. Also, unlike the CMP process removing a surface of a target layer in a contact type, the wet etching or the dry etching removes the target layer in a non-contact type. Thus, a defect like scratch does not occur on the surface of the lower electrode 32A.

Referring to FIG. 2F, a ferroelectric layer 35 is deposited on en entire surface of the above resulting structure containing the lower electrode 32A and the second insulation layer 34. Then, a second conductive layer for use in an upper electrode 36 is deposited thereon. Afterwards, the second conductive layer for use in the upper electrode 36 is selectively etched to form the upper electrode 36.

At this time, the ferroelectric layer 35 is deposited by using one of a PVD technique, a CVD technique, an ALD technique and a spin coating technique using MOD or sol-gels. Also, the ferroelectric layer 35 is made of a material selected from a group consisting of strontium bismuth tantalate (SBT), Lead Zirconate Titanate (PZT) and Bismuth lanthanum titanate (BLT) or a material selected from a group consisting of SBT, PZT, BLT and strontium bismuth tantalum niobate (SBTN) each containing an impurity or having changed composition ratios. In case of depositing BLT, the spin coating method is used. After the deposition of the BLT, a first baking process is applied thereto at a temperature ranging from about 150° C. to about 250° C. so that organic materials are removed. Then, a first RTP is performed at a temperature of about 475° C. in an atmosphere of oxygen (O₂) for about 60 seconds to remove organic materials and impurities. After the first RTP, a second RTP proceeds at a temperature of about 650° C. in an atmosphere of O₂ for about 120 seconds. At this time, the second RTP induces nucleus generation of the BLT. Lastly, the above resulting BLT is subjected to another thermal process performed at a temperature of about 650° C. in an atmosphere of O₂ for about 60 minutes by using a diffusion furnace in order to maximize crystallization of the BLT.

As described above, the ferroelectric layer 35 is formed on the structure containing buried lower electrode 32A. The ferroelectric layer 35 is then planarized before the upper electrode 36 is formed in order to construct more easily a planarized structure through subsequent processes.

In the meantime, the second conductive layer for use in the upper electrode 36 can be formed by using the same material adopted for the first conductive layer 32 used for the lower electrode 32A. Especially, the upper electrode 36 is patterned into a plateline form connecting several cells simultaneously.

By following the preferred embodiment of the present invention, it is possible to efficiently prevent occurrences of scratch on the lower electrode during the CMP process for forming the insulation layer encompassing the lower electrode. As a result of this effect, it is further possible to achieve stability of processes and reliability of devices.

While the present invention has been described with respect to certain preferred embodiments, it will be apparent to those skilled in the art that various changes and modifications may be made without departing from the scope of the invention as defined in the following claims.

1: A method for fabricating a ferroelectric memory device, comprising the steps of:
forming a first insulation layer on a substrate;
forming a storage node contact contacting to a partial portion of the substrate by passing through the first insulation layer;
forming a first conductive layer and a hard mask on the storage node contact on the first insulation layer, wherein the first conductive layer is patterned by using the hard mask, thereby obtaining a stack pattern;
forming a second insulation layer on the stack pattern;
planarizing the second insulation layer until a surface of the hard mask is exposed;
removing selectively the exposed hard mask to make a surface level of the lower electrode lower than that of the second insulation layer; and
forming sequentially a ferroelectric layer and an upper electrode on the second insulation layer and the lower electrode.

2: The method as recited in claim 1, wherein the hard mask is made of at least one of titanium nitride, and tantalum nitride.

3: The method as recited in claim 1, wherein the step of making the surface level of the lower electrode lower than that of the second insulation layer proceeds by performing a wet etching process or a dry etching process to the hard mask.

4: The method as recited in claim 3, wherein the wet etching process uses one of cleaning agents such as SC-1 comprising ammonium hydroxide (NH₄OH), hydrogen peroxide (H₂O₂) and water (H₂O) in a ratio of about 1 to about 4 to about 20 and SPM comprising sulfuric acid (H₂SO₄) and hydrogen peroxide (H₂O₂) in a ratio of about 4 to about 1.

5: The method as recited in claim 3, wherein the dry etching process uses a mixed gas of argon (Ar) and chlorine (Cl).

6: The method as recited in claim 1, wherein the step of planarizing the second insulation layer until the surface of the hard mask is exposed includes the steps of:
planarizing a partial portion of the second insulation layer by performing a chemical mechanical polishing (CMP) process; and
performing an etch-back process to the second insulation layer to make the hard mask exposed.

7: The method as recited in claim 1, wherein the step of planarizing the second insulation layer until the surface of the hard mask is exposed proceeds by applying a CMP process or an etch-back process at once to the second insulation layer.
